(19) United States
(12) Patent Application Publication
(10) Pub. No.: US 2018/0241410 A1
(43) Pub. Date: Aug. 23, 2018

(54) SIGNAL PROCESSING CIRCUIT AND SIGNAL PROCESSING METHOD

(71) Applicant: Kabushiki Kaisha Toshiba, Tokyo (JP)

(72) Inventors: Junichi Takeda, Yokohama Kanagawa (JP); Maho Kuwahara, Meguro Tokyo (JP); Masanori Matsuda, Edogawa Tokyo (JP); Masakazu Yaginuma, Yokosuka Kanagawa (JP)

(21) Appl. No.: 15/690,548

(22) Filed: Aug. 30, 2017

(30) Foreign Application Priority Data
Feb. 21, 2017 (JP) 2017-030050

(51) Int. Cl. H03M 1/12

(52) U.S. Cl. CPC H03M 1/1255; G06F 3/0418

(57) ABSTRACT

According to one embodiment, a signal processing circuit includes: (i) a plurality of input ends to which respective input signals are supplied; (ii) a plurality of signal processing paths that are provided to correspond to the input ends; (iii) a switching circuit that performs switching between connections of the input ends and signal processing paths; (iv) an output circuit that supplies, to one or more output ends, output signals of the signal processing paths in association with the respective input signals that are supplied to the input ends.

### CROSS-REFERENCE TO RELATED APPLICATIONS

This application is based upon and claims the benefit of priority from Japanese Patent Application No. 2017-30050, filed on Feb. 21, 2017; the entire contents of which are incorporated herein by reference.

### FIELD

Embodiments described herein relate generally to a signal processing circuit and a signal processing method.

### BACKGROUND

A device that is represented by a device in which touch detection is performed, such as a smartphone and a tablet terminal, is to process input signals sent simultaneously from many sensors while reducing errors between the signals. However, a variation between characteristics of elements constituting signal processing paths for processing the input signals etc. causes a variation between characteristics of gains, phases, offsets, etc. of the signal processing paths, even when circuit structures of the signal processing paths are the same. There exists a method for performing calibration so as to correct an error caused by the characteristic variation between the signal processing paths, however, a measurement environment is changed by a temperature change, a voltage change, or the like, and thus the calibration is to be performed at each time when the measurement environment is changed. A configuration, in which calibration is performed under various conditions and the result is tabled, is to include a storage, thereby leading to an increase in costs. Thus, a signal processing circuit and a signal processing method are desired that are able to reduce effects of a characteristic variation between signal processing paths in real time and easily.

### BRIEF DESCRIPTION OF THE DRAWINGS

FIG. 1 is a diagram illustrating a configuration of a signal processing circuit according to a first embodiment;

FIG. 2 is a diagram illustrating one example of a correspondence relation between inputs and outputs caused by switching between signal processing paths;

FIG. 3 is a flowchart illustrating a signal processing method according to a second embodiment;

FIGS. 4A to 4D are diagrams illustrating simulation results;

FIG. 5 is a diagram illustrating another example of the correspondence relation between inputs and outputs caused by switching of the signal processing paths;

FIG. 6 is a diagram illustrating a configuration of a signal processing circuit according to a third embodiment;

FIG. 7 is a diagram illustrating phase shifts in sampling;

FIG. 8 is a flowchart illustrating a signal processing method according to a fourth embodiment; and

FIG. 9 is a diagram illustrating a configuration of a signal processing circuit according to a fifth embodiment.

### DETAILED DESCRIPTION

According to one aspect of the embodiments, a signal processing circuit includes: (i) a plurality of input ends to which respective input signals are supplied; (ii) a plurality of signal processing paths that are provided to correspond to the input ends; (iii) a switching circuit that is provided between the input ends and the signal processing paths to perform switching between connections of the input ends and the signal processing paths; (iv) one or more output ends; and (v) an output circuit that supplies, to the one or more output ends, output signals of the signal processing paths in association with the respective input signals that are supplied to the input ends, in accordance with the switching performed by the switching circuit.

Exemplary embodiments of a signal processing circuit and a signal processing method according to the present application will be explained below in detail with reference to the accompanying drawings. The present disclosure is not limited to the following embodiments.

### First Embodiment

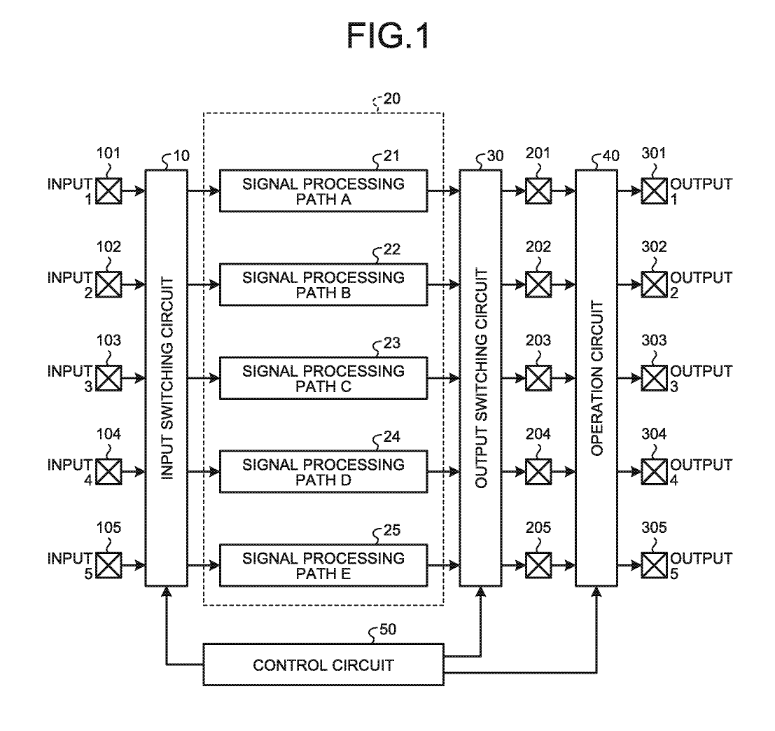

FIG. 1 is a diagram illustrating a configuration of a signal processing circuit according to a first embodiment. The signal processing circuit according to the present embodiment includes a plurality of input ends 101 to 105. Inputs 1 to 5 are supplied to the respective input ends 101 to 105. The inputs 1 to 5 are signals that are supplied from, for example, a touch panel (not illustrated).

The signal processing circuit according to the present embodiment further includes an input switching circuit 10. Outputs from the input switching circuit 10 are supplied to a signal processor 20.

The signal processor 20 includes signal processing paths 21 to 25, each of which corresponds to the corresponding one of the input ends 101 to 105. The input switching circuit 10 performs switching between connections of the input ends 101 to 105 and the signal processing paths 21 to 25. The input switching circuit 10 may have a configuration of a multiplexor that switches one or more connection destinations of each of the input ends 101 to 105 to any of the signal processing paths 21 to 25. For example, when the number of the input ends 101 to 105 is five and that of the signal processing paths 21 to 25 is also five, the input switching circuit 10 may have a configuration of a multiplexor that performs, under control of a control circuit 50, switching between connections of the five input ends 101 to 105 and five output ends connected with the signal processing paths 21 to 25.

Each of the signal processing paths 21 to 25 includes the same configuration elements (not illustrated) so as to include, for example, an amplifying circuit (not illustrated) and the like. Outputs of the signal processing paths 21 to 25 are supplied to an output switching circuit 30.

The output switching circuit 30 supplies outputs of the signal processing paths 21 to 25 to output ends 201 to 205 in association with the inputs 1 to 5 having been supplied to the input ends 101 to 105, in accordance with the switching, caused by the input switching circuit 10, between the connection relation of the input ends 101 to 105 and the signal processing paths 21 to 25. For example, when a signal processing path for processing the input 1 that is supplied to the input end 101 is switched from the signal processing path 21 to the signal processing path 22, the output switching circuit 30 supplies an output of the signal processing path 22 to the output end 201 that is associated with the input end 101. Thus, an output, which is associated with the input 1 having been supplied to the input end 101, is supplied to the output end 201. When similar switching is performed in performing the switching between the signal processing paths 21 to 25, the input ends 101 to 105 and the output ends 201 to 205 are able to be associated with one another. Note that the output switching circuit 30 may have, similarly to the input switching circuit 10, a configuration of a multiplexor that switches a supply destination of an output of each of the signal processing paths 21 to 25 into corresponding one of the output ends 201 to 205 so as to connect the corresponding signal processing path with the corresponding one of the output ends 201 to 205.

Outputs of the output ends 201 to 205 are supplied to an operation circuit 40. The operation circuit 40 executes predetermined operation processes on the outputs supplied from the output ends 201 to 205 so as to supply the processed outputs to output ends 301 to 305. The control circuit 50 controls the input switching circuit 10, the output switching circuit 30, and the operation circuit 40.

According to the first embodiment, switching operations are sequentially performed on the signal processing paths 21 to 25, which are for processing the inputs 1 to 5 supplied to the input ends 101 to 105, and each of the inputs 1 to 5 is supplied to corresponding one of the output ends 201 to 205. The switching is performed on the signal processing paths 21 to 25 for processing the inputs 1 to 5, whereby, even when there exists a variation between characteristics of the signal processing paths 21 to 25, this variation is averaged, so that it is possible to obtain an output whose error caused by the variation between the characteristics of the signal processing paths 21 to 25 is reduced. In other words, effects of the characteristic variation between the signal processing paths 21 to 25 are able to be reduced. By employing a configuration for performing switching between the signal processing paths 21 to 25 so as to change the connection relation between the signal processing paths 21 to 25 and the inputs 1 to 5, it is possible to reduce effects of characteristic variation between the signal processing paths 21 to 25 in real time and easily.

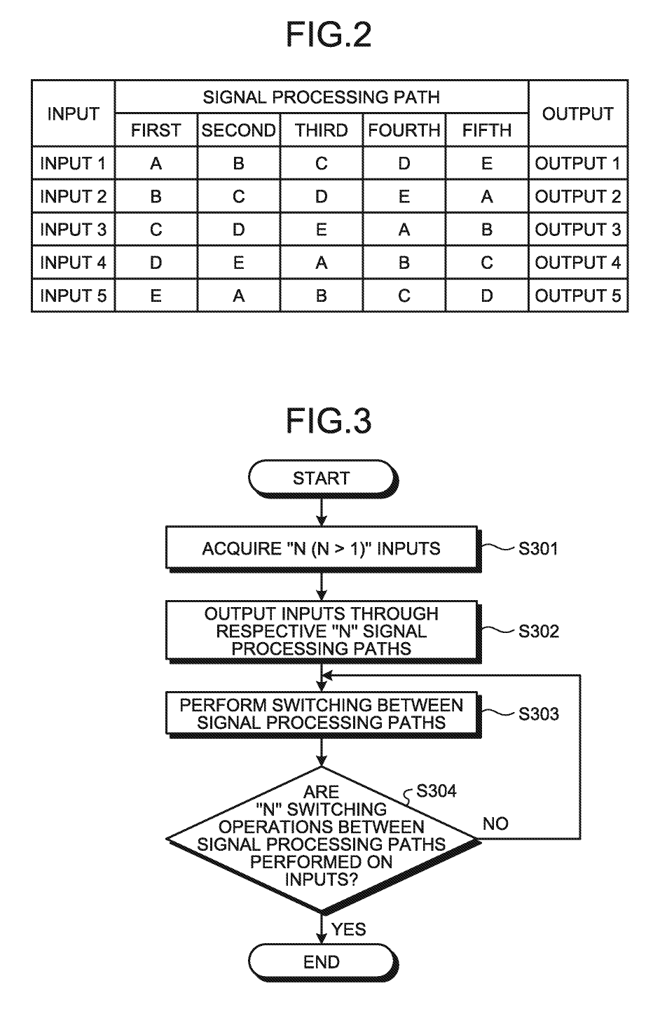

FIG. 2 is a diagram illustrating one example of a method for performing switching between the signal processing paths 21 to 25 in the signal processing circuit according to the first embodiment illustrated in FIG. 1. In FIG. 2, a correspondence relation between the inputs 1 to 5 and outputs 1 to 5 is illustrated. The inputs 1 to 5 in a left column indicate inputs to be supplied to the input ends 101 to 105 illustrated in FIG. 1.

For example, five switching operations between the signal processing paths 21 to 25 are performed until the outputs 1 to 5 are output. In a first signal processing, the input 1 is supplied to the signal processing path 21 that is indicated by “A”. An output of the input 1 processed by the signal processing path 21 is supplied, through the output switching circuit 30, to the output end 201 that is corresponding to the input end 101. Similarly, the inputs 2 to 5 are respectively processed by the signal processing paths 22 to 25, which are indicated by “B to E”, and then are supplied, through the output switching circuit 30, to the output ends 202 to 205 that are respectively corresponding to the input ends 102 to 105.

In a second signal processing, switching operations between the signal processing paths 21 to 25 are performed by the input switching circuit 10, and the input 1 is supplied to the signal processing path 22 that is indicated by “B”. Similarly, switching operations between the signal processing paths are performed on the inputs 2 to 5, and the inputs 2 to 5 are supplied to the signal processing paths 21 to 25 having the correspondence relation illustrated in FIG. 2.

Switching operations are performed so that each of the inputs 1 to 5 corresponds to all of the provided signal processing paths 21 to 25. The output switching circuit 30 supplies an output of each of the signal processing paths 21 to 25 to corresponding one of the output ends 201 to 205 that are respectively corresponding to the input ends 101 to 105, in accordance with the switching between the signal processing paths 21 to 25. In other words, processed signals of the input 1 that are processed by the signal processing paths 21 to 25 are output so as to be supplied to the output end 201. Similarly, signals each of which is processed by the signal processing paths 21 to 25 are output so as to be supplied to the output ends 202 to 205 that are corresponding to the respective other inputs 2 to 5.

Each of the outputs 1 to 5 of the output ends 301 to 305 may be a total value of the output signals, which corresponds to corresponding one of the inputs 1 to 5, obtained through the signal processing paths 21 to 25, for example. Alternatively, each of the outputs 1 to 5 may be an average value obtained by dividing the total value by the number of switching operations between the signal processing paths 21 to 25. The operation circuit 40 may be configured to perform the arithmetic operations.

### Second Embodiment

FIG. 3 is a flowchart illustrating a signal processing method according to a second embodiment. The signal processing method according to the present embodiment is performed by, for example, the signal processing circuit according to the first embodiment illustrated in FIG. 1. The inputs 1 to 5 are acquired, which are supplied to the input ends whose number is “N” (for example, the input ends 101 to 105) (Step S301). The inputs 1 to 5 are output through the signal processing paths, whose number is “N” (for example, the signal processing paths 21 to 25), corresponding to the input ends 101 to 105 (Step S302). The outputs of the signal processing paths 21 to 25 are supplied to the output ends 201 to 205 that are respectively corresponding to the input ends 101 to 105. Thus, a first signal process is executed by the signal processing paths 21 to 25.

Switching between the signal processing paths 21 to 25 is performed (Step S303). For example, a signal processing path for processing the input 1 is switched from the signal processing path 21 to the signal processing path 22. Similarly, switching operations are performed between the signal processing paths 21 to 25 for the inputs 2 to 5.

Whether or not switching operations between the “N” signal processing paths (for example, the signal processing paths 21 to 25) that are corresponding to the “N” inputs (for example, the inputs 1 to 5) are performed is determined (Step S304). In other words, whether or not each of the inputs 1 to 5 is processed by all of the signal processing paths 21 to 25 and the outputs are supplied to corresponding one of the output ends 201 to 205 is determined.

When switching operations to all of the signal processing paths 21 to 25 are performed (Step S304: Yes), the process is terminated. When the switching operations are not performed (Step S304: No), the switching between the signal processing paths 21 to 25 is continued.

By employing the signal processing method according to the present embodiment, each of the “N” inputs are supplied through the “N” signal processing paths (for example, the signal processing paths 21 to 25) on which the switching operations are sequentially performed, signal processing is performed on the supplied inputs, and the signal-processed inputs are output. Thus, even when there exists a characteristic variation between the signal processing paths 21 to 25, the variation is averaged, so that it is possible to reduce effects of the characteristic variation between the signal processing paths 21 to 25.

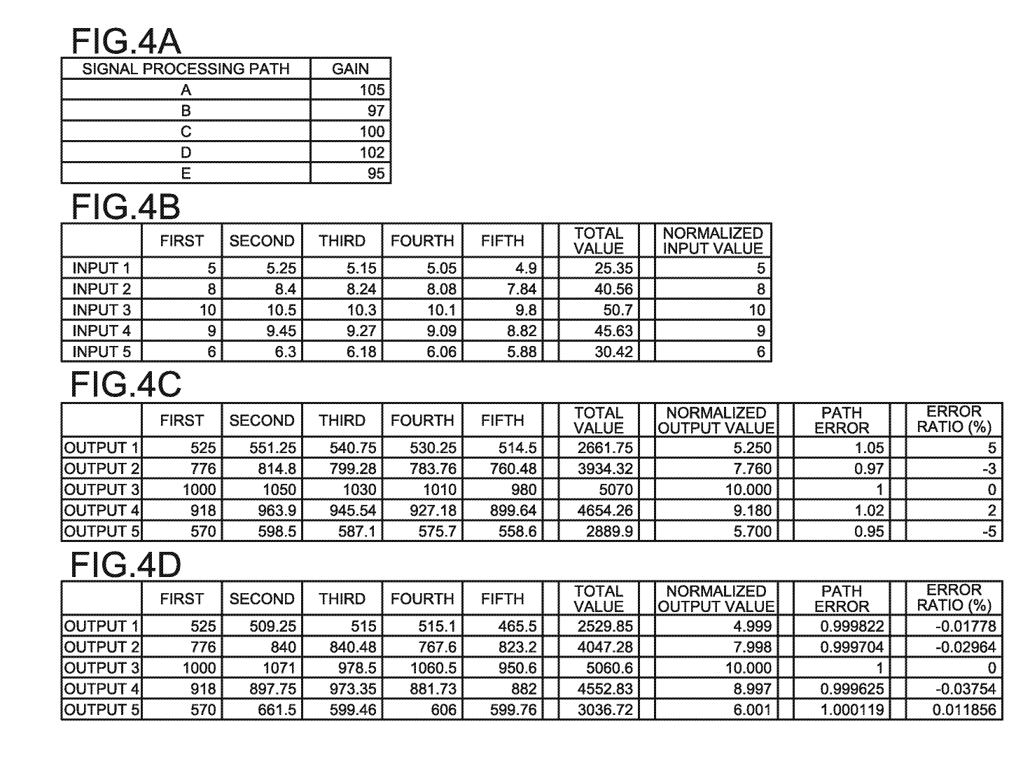

FIGS. 4A to 4D are diagrams illustrating simulation results. In FIG. 4A, gains of the signal processing paths 21 to 25 are illustrated. For convenience of explanation, the signal processing paths 21 to 25 of the signal processing circuit according to the embodiment illustrated in FIG. 1 are respectively indicated by “A” to “E”.

The inputs 1 to 5 that are to be supplied to the respective input ends 101 to 105 are illustrated in FIG. 4B. In this simulation, the inputs 1 to 5 are changed which are supplied in timings of first to fifth signal processes. A total value indicates a total value of values of each of the inputs 1 to 5 that are supplied in the first to fifth signal processes, in other words, during switching operations of the signal processing paths 21 to 25. A normalized input value indicates what is normalized by using the input 3 as a reference, and, for convenience of explanation, indicates a value obtained by dividing the total value of the input values by a value of one tenth of the total value of the input 3, in other words, “5.07”.

In FIG. 4C, the case is illustrated in which the signal processing path 21 is fixedly connected with the output ends 201 (301) to which the output 1 is to be output without any switching between the signal processing paths 21 to 25 to be performed by the input switching circuit 10 and the output switching circuit 30. Similarly, each of the specific signal processing paths 22 to 25 is fixedly connected with corresponding one of the output ends 202 to 205 (302 to 305).

Therefore, as the output 1 illustrated in FIG. 4C, a signal is output that is obtained by multiplying the input 1 in each of the timings of the first to fifth signal processes by a gain “105” of the signal processing path 21. The same process is performed with respect to each of the other output 2 to 5. A total value is a value obtained by totalizing first to fifth outputs. A normalized output value indicates what is normalized by using the output 3 as a reference, and, for convenience of explanation, indicates a value obtained by dividing the total value of the output values by a value of one tenth of the total value of the input 3, in other words, “507”.

A path error indicates a value obtained by dividing each of the normalized outputs by the corresponding normalized input value. An error ratio indicates a value indicating a difference of the path error from “1” in percentages.

Any switching between the signal processing paths 22 to 25 is not performed in the simulation illustrated in FIG. 4C, and thus a variation between gains of the signal processing paths 22 to 25 is reflected on the path errors as it is. Thus, a range of error ratios between the signal processing paths 22 to 25 is from −5% to 5%.

The simulation result, in which the input switching circuit 10 performs switching operations between the signal processing paths 21 to 25 in the first to fifth signal processes, is illustrated in FIG. 4D. The switching operations between the signal processing paths 21 to 25 in this simulation are corresponding to the switching method illustrated in FIG. 2. In other words, the input 1 is output to the output end 201 (301) through the signal processing path A in the first signal process, and the input 1 is output to the output end 201 (301) through the signal processing path that is switched into “B→C→D→E” in this order in the second signal process and the following. Similarly, switching operations are sequentially performed on the signal processing paths 21 to 25 of each of the other inputs 2 to 5 in the correspondence relation illustrated in FIG. 2.

As a result, a signal is output as the output 1, which is obtained, in the first signal processing, by multiplying the input 1 by a gain “105” of the signal processing path 21. In each of the second signal processing and the following, a signal obtained by multiplying the input 1, which is supplied in a corresponding switch timing, by a gain of corresponding one of the signal processing paths 22 to 25 through which the input 1 is processed in accordance with the switching.

A total value indicates a total value of outputs obtained by first to fifth signal processes of the signal processing paths 21 to 25. The same process is performed with respect to each of the other output 2 to 5. A normalized output value is obtained by normalizing each of the output values by using the output 3 as a reference, and, for convenience of explanation, indicates a value obtained by dividing a total value of the outputs by a value of one tenth of the total value of the output 3, in other words, “506.06”.

A path error is a value obtained by dividing each of the normalized outputs by the corresponding normalized input value illustrated in FIG. 4B. In other words, the path error of the output 1 is a value obtained by dividing a normalized output value “4.999” by a normalized input value “5”. An error ratio indicates a value indicating a difference of the path error from “1” in percentages.

As indicated by the simulation result illustrated in FIG. 4D, a range of the error ratios between the signal processing paths becomes from −0.01778% to 0.0011856% by the switching operations between the signal processing paths 21 to 25. It is found that the error ratios are largely reduced compared with those obtained with no switching operations between the signal processing paths 21 to 25, whose range is from −5% to 5% as illustrated in FIG. 4C.

When values of the inputs 1 to 5 at the first to fifth timings illustrated in FIG. 4B are the same in the switching operations between the signal processing paths 21 to 25 which are explained in FIG. 4D, all of the path errors for the inputs 1 to 5 become “1”, and thus the error ratios become 0%.

For example, in the first embodiment illustrated in FIG. 1, when switching is performed on the signal processing paths 21 to 25 so fast that a change between the inputs 1 to 5 supplied to the input ends 101 to 105 is able to be neglected, the inputs 1 to 5 having substantially the same values are supplied to the signal processing paths 21 to 25 on which the switching is performed. This case may occur in a signal process etc. when a touch panel (not illustrated) is depressed for a long time.

Alternatively, in the first embodiment illustrated in FIG. 1, a configuration may be employed, in which a holding circuit (not illustrated) for temporarily holding the inputs 1 to 5 is provided between the input ends 101 to 105 and the input switching circuit 10 or between the input switching circuit 10 and the signal processor 20 including the signal processing paths 21 to 25, and the inputs 1 to 5, which are temporarily held in the holding circuit until a predetermined process for performing switching between the signal processing paths 21 to 25 ends, are supplied to the signal processing paths 21 to 25 so that each of the inputs 1 to 5 that has the same value, in other words, whose value is constant, is able to be supplied to the signal processing paths 21 to 25.

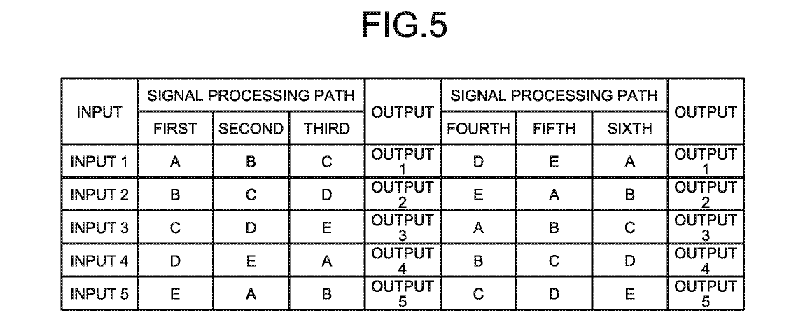

FIG. 5 is a diagram illustrating another example of the method for performing switching between the signal processing paths 21 to 25 in the signal processing circuit according to the first embodiment illustrated in FIG. 1. In FIG. 5, a correspondence relation between the inputs 1 to 5 and the outputs 1 to 5 is illustrated. The inputs 1 to 5 in a left column indicate inputs to be supplied to the input ends 101 to 105 illustrated in FIG. 1. In a case of this example, switching between the signal processing paths 21 to 25 is performed at three times so that the first outputs 1 to 5 corresponding to the respective inputs 1 to 5 are obtained. In other words, a signal process through the signal processing path 21, which is indicated by “A”, is performed on the input 1 in the first signal process, and switching operations to the signal processing paths 22, 23, which are indicated by “B” and “C”, are performed in the respective second and third signal processes. Similarly, switching operations to the three signal processing paths are performed on each of the inputs 2 to 5 so that the outputs 2 to 5 are obtained.

Three switching operations between the signal processing paths 21 to 25 are performed on each of the inputs 1 to 5 so as to output the second outputs 1 to 5 illustrated on the right column side. In other words, in the case illustrated in FIG. 2, the outputs 1 to 5 are obtained after switching operations are performed on all of the signal processing paths 21 to 25 with respect to each of the inputs 1 to 5, in the example of the processing method illustrated in FIG. 5, the outputs are obtained by performing three switching operations between the signal processing paths on each of the inputs 1 to 5. Each of the outputs 1 to 5 may be a total value of the outputs obtained by using the three signal processing paths caused by the switching operations. Alternatively, the outputs 1 to 5 may be obtained by operating values that are normalized by using a specific output as a reference.

The switching between the signal processing paths 21 to 25 for processing the inputs 1 to 5 is performed for predetermined times so as to obtain the outputs 1 to 5, whereby it is possible to reduce effects of a characteristic variation between the signal processing paths 21 to 25.

### Third Embodiment

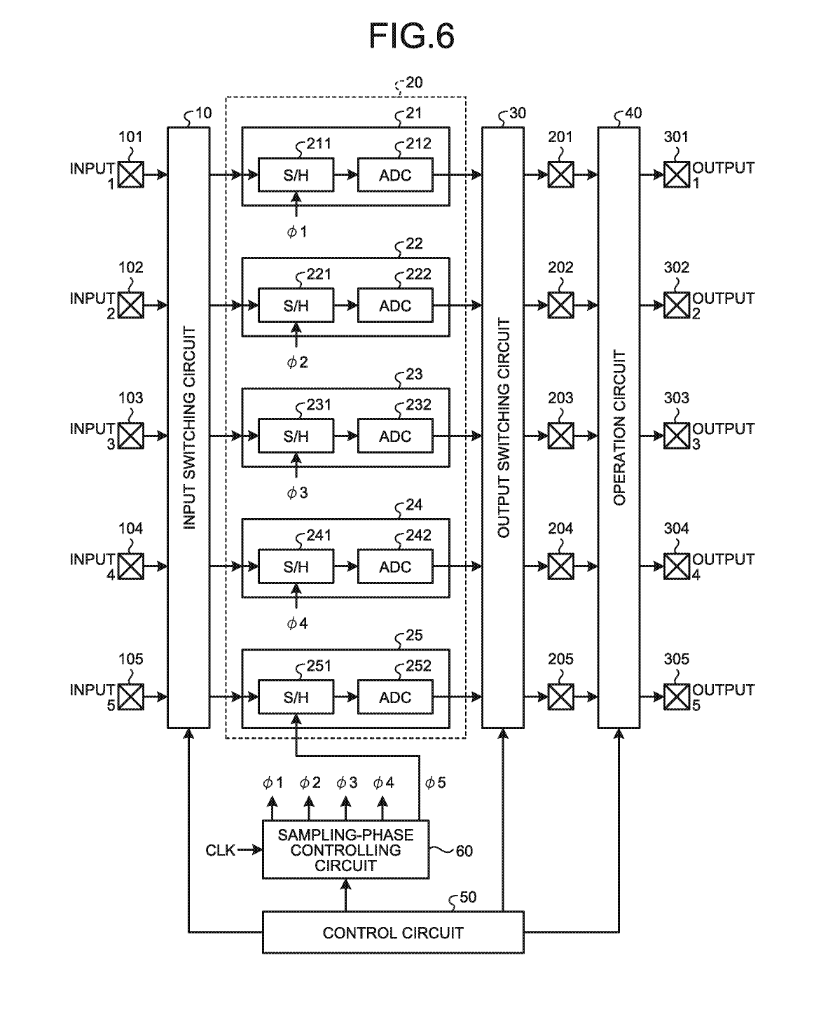

FIG. 6 is a diagram illustrating a configuration of a signal processing circuit according to a third embodiment. Hereinafter, configuration elements corresponding to those according to the above embodiment are provided with the same reference symbols, and duplicated description will be appropriately omitted. The signal processing paths 21 to 25 provided in the signal processing circuit according to the present embodiment include sample and hold circuits 211, 221, 231, 241, 251 and analog-to-digital conversion circuits (ADC) 212, 222, 232, 242, 252. In other words, the inputs 1 to 5 supplied through the input switching circuit 10 are converted into digital signals so as to be supplied to the output switching circuit 30.

A sampling-phase controlling circuit 60 generates sampling signals φ1 to φ5 from a clock signal CLK, and supplies the generated sampling signals φ1 to φ5 to the respective sample and hold circuits 211, 221, 231, 241, 251. Each of the sample and hold circuits 211, 221, 231, 241, 251 samples a signal, which is supplied from the input switching circuit 10, in synchronization with corresponding one of the sampling signals φ1 to φ5 that are supplied from the sampling-phase controlling circuit 60.

The control circuit 50 controls the input switching circuit 10, the sampling-phase controlling circuit 60, the output switching circuit 30, and the operation circuit 40. For example, the control circuit 50 shifts the phases of the sampling signals φ1 to φ5, which are output by the sampling-phase controlling circuit 60, in accordance with switching of the input switching circuit 10.

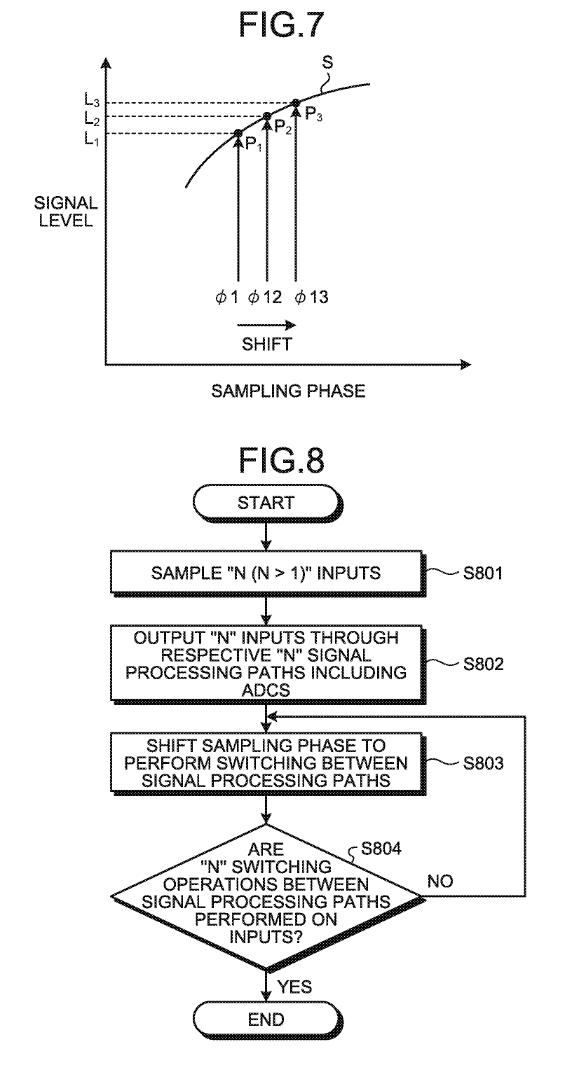

FIG. 7 is a diagram illustrating phase shifts of the sampling signals φ1 to φ5 and effects thereof. Phase shift of the sampling signal φ1 of an input S from φ1 to φ12 and then φ13 changes detection position (P₁ to P₃) of the input S. Thus, signal level (L₁ to L₃) for quantizing the input S is changed.

There is known a fact that, when the signal level (L₁ to L₃) for detecting the input S is changed by shifting the phase of the sampling signal φ1 for quantizing the input S and outputs thereof are averaged, a quantization error is able to be reduced as a whole. The effects of the characteristic variation between the signal processing paths 21 to 25 are able to be reduced by sequentially performing switching operations on the signal processing paths 21 to 25 for processing the inputs and the quantization errors of the ADC 212, 222, 232, 242, 252 of the respective signal processing paths 21 to 25 are able to be reduced by shifting the phases of the sampling signals φ1 to φ5 in accordance with the switching between the signal processing paths 21 to 25. In other words, the quantization errors are able to be reduced and further effects of the characteristic variation between the signal processing paths 21 to 25 are able to be reduced.

The phases of the sampling signals φ1 to φ5 that are supplied to the signal processing paths 21 to 25 may be the same or different from one another. When the phases of the sampling signals φ1 to φ5 are the same, a configuration may be employed in which the phases of the sampling signals φ1 to φ5 are shifted similarly to one another in accordance with switching between the signal processing paths 21 to 25. When the phases of the sampling signals φ1 to φ5 are different from one another, effects similar to those obtained by shifting the phases of the sampling signals are able to be obtained by switching between the signal processing paths 21 to 25. Note that, when the phases of the sampling signals φ1 to φ5 are different from one another, a configuration may be employed in which the phases of the sampling signals φ1 to φ5 are individually shifted in accordance with switching between the signal processing paths 21 to 25.

### Fourth Embodiment

FIG. 8 is a flowchart illustrating a signal processing method according to a fourth embodiment. The signal processing method according to the present embodiment is performed by, for example, the signal processing circuit according to the third embodiment illustrated in FIG. 6. The “N” inputs (for example, the inputs 1 to 5) supplied to the input ends 101 to 105 are sampled (Step S801). For example, the sample and hold circuits 211, 221, 231, 241, 251 of the signal processing paths 21 to 25 sample the inputs 1 to 5 in synchronization with the sampling signals φ1 to φ5.

The sampled inputs 1 to 5 are output through the signal processing paths 21 to 25 including the ADC 212, 222, 232, 242, 252 (Step S802). In this case, the inputs 1 to 5 are converted into respective digital signals by the ADC 212, 222, 232, 242, 252 of the signal processing paths 21 to 25.

The phases in sampling are shifted and switching is performed on the signal processing paths (Step S803). In other words, similarly to the above embodiment, a connection destination of each of the signal processing paths 21 to 25, which is to be connected with corresponding one of the input ends 101 to 105, is changed by the input switching circuit 10, for example. Thus, effects of a characteristic variation between the signal processing paths 21 to 25 is able to be reduced.

The phase shift in sampling may be performed by relatively shifting the phases of the sampling signals φ1 to φ5 with a predetermined period, which are supplied from the sampling-phase controlling circuit 60, for example. When the phases of the sampling signals φ1 to φ5 are shifted, it is possible to reduce effects of quantization errors. As a result, both (i) reduction in effects of a characteristic variation between the signal processing paths caused by switching between the signal processing paths 21 to 25 and (ii) reduction in quantization errors of the signal processing paths 21 to 25 including the ADCs are able to be simultaneously realized.

Whether or not switching operations between the “N” signal processing paths (for example, the signal processing paths 21 to 25) that are corresponding to the “N” inputs (for example, the inputs 1 to 5) are performed is determined (Step S804). When switching operations to the “N” signal processing paths (for example, the signal processing paths 21 to 25) are performed (Step S804: Yes), the process is terminated. When the switching operations to the “N” signal processing paths (for example, the signal processing paths 21 to 25) are not performed (Step S804: No), the shift of the sample phases and the switching between the signal processing paths 21 to 25 are continued.

By employing the signal processing method according to the present embodiment, it is possible to reduce effects of a characteristic variation between the signal processing paths 21 to 25 by switching between the signal processing paths 21 to 25. Moreover, it is possible to reduce quantization errors by shifting the phases of the sampling signals φ1 to φ5 of the signal processing paths 21 to 25 including the ADCs.

The phase shift in sampling and the switching between the signal processing paths (Step S803) may be performed in a control method for simultaneously controlling both the switching between the signal processing paths 21 to 25 and the shift of the phases of the sampling signals φ1 to φ5.

### Fifth Embodiment

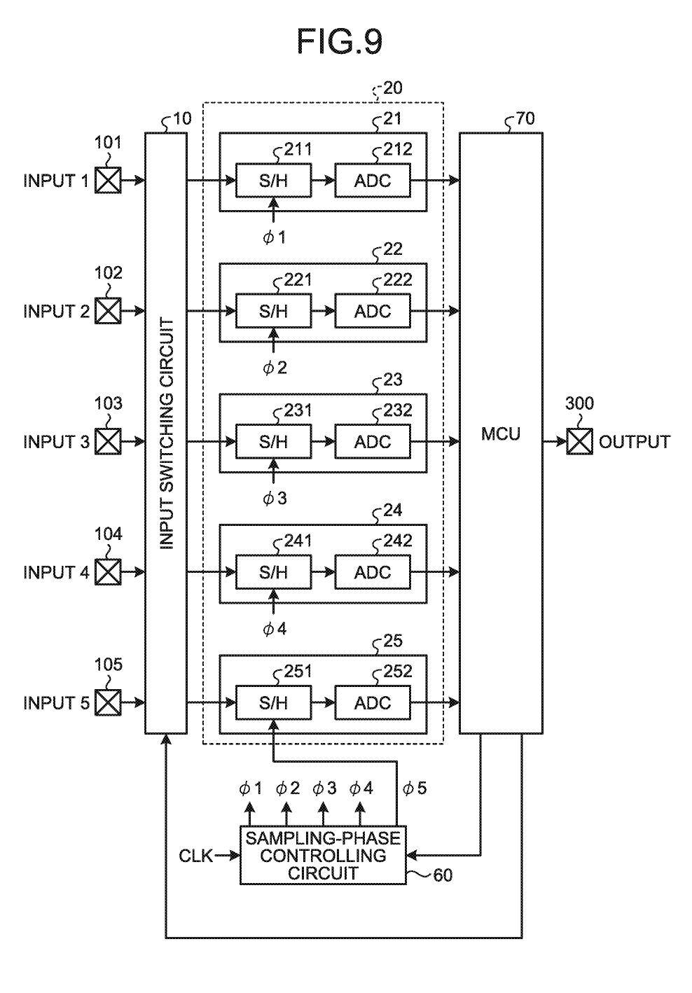

FIG. 9 is a diagram illustrating a configuration of a signal processing circuit according to a fifth embodiment. The signal processing circuit according to the present embodiment includes a micro-controller unit (MCU) 70 to which outputs of the signal processing paths 21 to 25 are supplied.

The MCU 70 supplies output signals of the signal processing paths 21 to 25 to an output end 300 in association with the inputs 1 to 5 supplied to the respective input ends 101 to 105, in accordance with switching between the signal processing paths 21 to 25 performed by the input switching circuit 10. For example, the output signals are supplied to the output end 300 while associating the outputs from the signal processing paths 21 to 25 with the inputs 1 to 5 in response to switching between the signal processing paths 21 to 25 to which the inputs 1 to 5 are supplied. By employing the association using the output order performed by the MCU 70, alternatively, addition of predetermined identification signals to the outputs performed by the MCU 70, each of the inputs 1 to 5 is able to be associated with a corresponding output that is to be supplied to the output end 300. The outputs are output in association with the respective inputs 1 to 5, and thus it is sufficient that the number of the output ends 300 to which the outputs of the MCU 70 are supplied is one. The MCU 70 controls the input switching circuit 10 and the sampling-phase controlling circuit 60.

The signal processing paths 21 to 25 output signals that are digitalized by the respective ADCs 212, 222, 232, 242, 252. By employing the MCU 70 having the arithmetic function, a configuration is able to be realized, in which a total value of the outputs obtained through the signal processing paths 21 to 25, alternatively, an average value of the outputs obtained by the switching between the signal processing paths 21 to 25 is output.

The signal processing circuit according to the present embodiment includes the MCU 70 that controls switching between the signal processing paths 21 to 25 and supplies, to the output end 300, each of the outputs of the signal processing paths 21 to 25 in association with the corresponding one of inputs 1 to 5 that are supplied to the respective input ends 101 to 105. Thus, the output switching circuit 30 and the control circuit 50 according to the embodiment illustrated in FIG. 1 as well as the operation circuit 40 are able to be omitted, so that it is possible to simplify the configuration of the signal processing circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A signal processing circuit comprising:
a plurality of input ends to which respective input signals are supplied;
a plurality of signal processing paths that are provided to correspond to the input ends;
a switching circuit that is provided between the input ends and the signal processing paths to perform a predetermined number of switching operations between connections of the input ends and the signal processing paths;
one or more output ends; and
an output circuit configured to:
generate an average value obtained by dividing by the predetermined number a total value of signals supplied from the signal processing paths in response to the predetermined number of switching operations for each of the input signals; and
supply, to the one or more output ends, output signals based on the average values in association with the respective input signals that are supplied to the input ends.

2. The signal processing circuit according to claim 1, wherein each of the signal processing paths includes an analog-to-digital convertor that converts, into a digital signal, a signal sampled in response to a predetermined sampling signal.

3. The signal processing circuit according to claim 1, wherein the output circuit controls the switching performed by the switching circuit.

4. The signal processing circuit according to claim 2, further comprising
a sampling-signal supplying circuit that supplies each of the analog-to-digital convertors with the corresponding predetermined sampling signal, wherein
the sampling-signal supplying circuit shifts phases of the sampling signals in accordance with the switching between the signal processing paths performed by the switching circuit.

5. The signal processing circuit according to claim 1, wherein the output circuit adds predetermined identification signals corresponding to the input ends to the respective output signals of the signal processing paths, and supplies the added output signals to the one or more output ends.

6. The signal processing circuit according to claim 1, wherein
the output ends correspond to the respective signal processing paths, and
when switching operations between the signal processing paths are sequentially performed, the output signals corresponding to the input signals that are respectively input to the input ends are supplied to the output ends associated with the input ends to which the input signals are input.

7. (canceled)

8. The signal processing circuit according to claim 1, wherein the output circuit executes a predetermined arithmetic operation on the output signals of the signal processing paths to supply the processed output signals to the one or more output ends.

9. A signal processing circuit comprising:
a plurality of input ends to which respective input signals are supplied;
a plurality of signal processing paths that are provided to correspond to the input ends;
an input switching circuit that is provided between the input ends and the signal processing paths to perform switching between connections of the input ends and the signal processing paths;
a plurality of output ends that are provided to correspond to the input ends;
an output switching circuit that is provided between the signal processing paths and the output ends to perform switching between connections of the signal processing paths and the output ends;
an operation circuit that is connected with the output ends; and
a control circuit that controls the input switching circuit and the output switching circuit, wherein the control circuit controls the input switching circuit to perform a predetermined number of switching operations between the connections of the input ends and the signal processing paths, and controls, at each time when the switching is performed, the output switching circuit so that the signals supplied to the respective input ends are to be supplied, through the respective signal processing paths whose connections to the input ends are changed by the switching, to the output ends corresponding to the respective input ends, and
wherein the operational circuit obtains an average value of each of output signals supplied to the respective output ends from the signal processing paths in response to the predetermined number of switching operations between connections of the input ends and the signal processing paths is performed.

10. (canceled)

11. (canceled)

12. The signal processing circuit according to claim 9, wherein each of the signal processing paths includes an analog-to-digital convertor that converts, into a digital signal, a signal sampled in response to a predetermined sampling signal.

13. The signal processing circuit according to claim 12, further comprising
a sampling-signal supplying circuit that supplies each of the analog-to-digital convertors with the corresponding predetermined sampling signal, wherein
the control circuit controls the sampling-signal supplying circuit to control phases of the sampling signals supplied to the analog-to-digital convertors.

14. The signal processing circuit according to claim 13, wherein the sampling-signal supplying circuit supplies the sampling signals having phases that are different from one another to the analog-to-digital convertors of the signal processing paths.

15. (canceled)

16. A signal processing method comprising:
supplying input signals to a plurality of input ends, respectively;
supplying the input signals, which are supplied to the input ends, to a plurality of signal processing paths on which a predetermined number of switching operations are sequentially performed, the signal processing paths being provided to correspond to the input ends;
generating an average value obtained by dividing by the predetermined number a total value of signals corresponding to the respective input signals output from the signal processing paths in response to the predetermined number of switching operations; and
outputting output signals of the signal processing paths based on the average values in association with the respective input signals that are supplied to the input ends.

17. The signal processing method according to claim 16 further comprising:
converting the input signals into digital signals in synchronization with predetermined sampling signals in the signal processing paths; and
shifting phases of the sampling signals in accordance with switching between the signal processing paths.

18. The signal processing method according to claim 16, wherein the outputting includes supplying the input signals, which are supplied to the respective input ends, to a plurality of output ends that are provided to correspond to the respective input ends.

19. (canceled)

20. The signal processing method according to claim 16, wherein the outputting includes adding, to the output signals, predetermined identification signals corresponding to the input ends to output the output signals to which the predetermined identification signals are added.
